(19) United States
(12) Patent Application Publication
(10) Pub. No.: US 2026/0293457 A1
(43) Pub. Date: Sep. 24, 2026

(54) Display Substrate and Display Device

(71) Applicants: MIANYANG BOE OPTOELECTRONICS TECHNOLOGY CO.,Ltd., Mianyang, Sichuan (CN); BOE Technology Group Co., Ltd., Beijing (CN)

(72) Inventors: Ning LUO, Beijing (CN); Chao QI, Beijing (CN); Jianhui YOU, Beijing (CN); Jinlong SANG, Beijing (CN); Yameng SUN, Beijing (CN); Yaojin YIN, Beijing (CN); Yingfan YANG, Beijing (CN)

(21) Appl. No.: 18/881,274

(22) PCT Filed: Aug. 15, 2024
(86) PCT No.: PCT/CN2024/112306

§ 371 Date: Jan. 4, 2025

(30) Foreign Application Priority Data
Sep. 27, 2023 (CN) 202311267001.8

(51) Int. Cl. H10K 59/131; H10K 59/121

(52) U.S. Cl. CPC H10K 59/131; H10K 59/1213

(57) ABSTRACT

A display substrate and a display device are provided. The display substrate includes a base substrate (10) including a display area and a first bezel area; multiple sub-pixels; multiple data lines electrically connected to the multiple sub-pixels; multiple data line lead lines (50) located in the first bezel area, the multiple data line lead lines (50) being electrically connected with the multiple data lines; and multiple drive chip pins (53) located in the first bezel area. One of the drive chip pins (53) is electrically connected to a data line lead line (50), and the multiple drive chip pins (53) are located on a side of the multiple data line lead lines (50) away from the base substrate (10). At least one groove structure (60) is provided on a surface on a side of the drive chip pin (53) away from the base substrate (10).

### CROSS-REFERENCE TO RELATED APPLICATION

The present application is a U.S. National Phase Entry of International Application No. PCT/CN2024/112306 having an international filing date of Aug. 15, 2024, which claims priority to Chinese patent application No. 202311267001.8, filed to the CNIPA on Sep. 27, 2023 and entitled “Display Substrate and Display Device”. Contents of the above-identified applications are incorporated into the present application by reference.

### TECHNICAL FIELD

The present disclosure relates to, but is not limited to, the field of display technologies, and particularly relates to a display substrate and a display device.

### BACKGROUND

With the continuous development of display technologies, structural forms of display substrates are also diversified. Low Temperature Polycrystalline Oxide (LTPO) display substrate integrates low-temperature poly-silicon thin film transistors and oxide thin film transistors on a same display substrate. The LTPO display substrate may achieve high resolution (Pixel Per Inch, PPI) and low-frequency driving, which may reduce the power consumption of the display device and improve the display quality of the display device.

### SUMMARY

The following is a summary of subject matters described herein in detail. This summary is not intended to limit the protection scope of claims.

Embodiments of the present disclosure provide a display substrate and a display device.

In a first aspect, an embodiment of the present disclosure provides a display substrate, including: a base substrate, including a display area and a first bezel area located on a side of the display area; multiple sub-pixels, located in the display area; multiple data lines, located in the display area, the multiple data lines being electrically connected to the multiple sub-pixels; multiple data line lead lines, located in the first bezel area, the multiple data line lead lines being electrically connected to the multiple data lines; and multiple drive chip pins, located in the first bezel area, a drive chip pin being electrically connected to a data line lead line, and the multiple drive chip pins being located on a side of the multiple data line lead lines away from the base substrate.

At least one groove structure is provided on a surface on a side of the drive chip pin away from the base substrate, the at least one groove structure includes a groove bottom and a groove wall connecting the groove bottom, the at least one groove structure has a groove depth in a thickness direction of the display substrate, and the groove depth ranges from 0.40 micron to 0.65 micron.

In an exemplary embodiment, in a plane perpendicular to the display substrate, the first bezel area includes a first metal layer, a second metal layer, a third metal layer, and a fourth metal layer that are provided on a side of the base substrate and are stacked sequentially; the first metal layer includes the multiple data line lead lines and the fourth metal layer includes the multiple drive chip pins.

In an exemplary embodiment, in the plane perpendicular to the display substrate, the first bezel area further includes at least one insulation layer, and the at least one insulation layer is located between the first metal layer and the second metal layer; the second metal layer includes at least one connection electrode, and a portion of the connection electrode is located in a via of the at least one insulation layer, and is in contact and connected with a surface on a side of the data line lead line away from the base substrate.

In an exemplary embodiment, the at least one insulation layer includes a first inorganic layer and a second inorganic layer, and the second inorganic layer is farther away from the base substrate than the first inorganic layer. In a line width direction of the data line lead line, an orthographic projection of a via provided in the first inorganic layer on the display substrate is located within an orthographic projection of the data line lead line on the display substrate, an orthographic projection of a via provided in the second inorganic layer on the display substrate includes the orthographic projection of the data line lead line on the display substrate, and the orthographic projection of the via provided in the second inorganic layer on the display substrate is larger than the orthographic projection of the data line lead line on the display substrate.

In an exemplary embodiment, one insulation layer is provided between the first metal layer and the second metal layer, and in a line width direction of the data line lead line, an orthographic projection of the via provided in the insulation layer on the display substrate is located within an orthographic projection of the data line lead line on the display substrate.

In an exemplary embodiment, in the plane perpendicular to the display substrate, the display area includes a first gate metal layer, a second gate metal layer, a first source-drain metal layer, and a second source-drain metal layer that are provided on a side of the base substrate and stacked sequentially. The first metal layer and the first gate metal layer are structures provided in a same layer, the second metal layer and the first source-drain metal layer are structures provided in a same layer, and the third metal layer and the second source-drain metal layer are structures provided in a same layer.

In an exemplary embodiment, in the plane perpendicular to the display substrate, the display area includes a first gate metal layer, a second gate metal layer, a first source-drain metal layer, and a second source-drain metal layer that are provided on a side of the base substrate and stacked sequentially. The first metal layer and the second gate metal layer are structures provided in a same layer, the second metal layer and the first source-drain metal layer are structures provided in a same layer, and the third metal layer and the second source-drain metal layer are structures provided in a same layer.

In an exemplary embodiment, the second metal layer includes at least one first connection electrode and the third metal layer includes at least one second connection electrode; at least a portion of a surface on a side of the second connection electrode away from the base substrate is in contact and connected with the groove structure of the drive chip pin, and a portion of a surface on a side of the first connection electrode close to the base substrate is in contact and connected with the data line lead line.

In an exemplary embodiment, the first connection electrode has a first sub-groove, the second connection electrode has a second sub-groove, an orthographic projection of the groove structure of the drive chip pin on the display substrate is located within an orthographic projection of the second sub-groove on the display substrate, and the orthographic projection of the second sub-groove on the display substrate is located within an orthographic projection of the first sub-groove on the display substrate.

In an exemplary embodiment, in the plane perpendicular to the display substrate, the first bezel area further includes a leveling layer and the leveling layer is located between the base substrate and the first metal layer; the leveling layer includes at least one leveling block; in a line width direction of the data line lead line, an orthographic projection of the data line lead line on the display substrate includes an orthographic projection of the leveling block on the display substrate.

In an exemplary embodiment, in the plane perpendicular to the display substrate, the first bezel area further includes a leveling layer, the leveling layer is located between the first metal layer and the second metal layer, and the leveling layer includes at least one leveling block; in a line width direction of the data line lead line, an orthographic projection of the leveling block on the display substrate includes an orthographic projection of the data line lead line on the display substrate, and the data line lead line is electrically connected to the groove structure of the drive chip pin via the leveling block.

In an exemplary embodiment, in the plane perpendicular to the display substrate, the first bezel area further includes at least one insulation layer, the at least one insulation layer is located between the first metal layer and the second metal layer, and a surface on a side of the at least one insulation layer away from the base substrate is flush with a surface on a side of the data line lead line and the leveling block away from the base substrate.

In an exemplary embodiment, the second metal layer includes at least one first connection electrode and the third metal layer includes at least one second connection electrode; the data line lead line is connected to the groove structure of the drive chip pin via the first connection electrode and the second connection electrode. A surface on a side of the first connection electrode away from the base substrate is planar.

In an exemplary embodiment, a surface on a side of the second connection electrode away from the base substrate is planar.

In an exemplary embodiment, in the plane perpendicular to the display substrate, the display area includes a first gate metal layer, a second gate metal layer, a first source-drain metal layer, and a second source-drain metal layer that are provided on a side of the base substrate and stacked sequentially; the second metal layer and the first source-drain metal layer are structures provided in a same layer, and the third metal layer and the second source-drain metal layer are structures provided in a same layer.

The leveling layer and one of the first gate metal layer and the second gate metal layer are structures provided in a same layer and the first metal layer and the other of the first gate metal layer and the second gate metal layer are structures provided in a same layer.

In another aspect, an embodiment of the present disclosure provides a display device, and the display device includes the display substrate described in any one of the above embodiments.

Other aspects of the present disclosure may be comprehended after the drawings and the detailed descriptions are read and understood.

### BRIEF DESCRIPTION OF DRAWINGS

Accompanying drawings are intended to provide an understanding of technical solutions of the present application and form a part of the specification, and are used to explain the technical solutions of the present application together with embodiments of the present application, and do not constitute a limitation on the technical solutions of the present application.

FIG. 1 is a schematic diagram of a structure of a display device according to an embodiment of the present disclosure.

FIG. 2 is a schematic planar view of a display substrate according to an embodiment of the present disclosure.

FIG. 3 is a schematic partial sectional view of a display area of a display substrate according to an embodiment of the present disclosure.

FIG. 4 is a first schematic partial sectional view of a drive chip pin of a display substrate according to an embodiment of the present disclosure.

FIG. 5 is a second schematic partial sectional view of a drive chip pin of a display substrate according to an embodiment of the present disclosure.

FIG. 6 is a third schematic partial sectional view of a drive chip pin of a display substrate according to an embodiment of the present disclosure.

FIG. 7 is a fourth schematic partial sectional view of a drive chip pin of a display substrate according to an embodiment of the present disclosure.

FIG. 8 is a fifth schematic partial sectional view of a drive chip pin of a display substrate according to an embodiment of the present disclosure.

FIGS. 9A-9G are schematic diagrams of a manufacturing process of a drive chip pin of a display substrate according to an embodiment of the present disclosure.

FIG. 10 is a schematic partial sectional view of a drive chip pin of a display substrate according to another embodiment of the present disclosure.

FIG. 11 is a first schematic partial sectional view of a drive chip pin of a display substrate according to yet another embodiment of the present disclosure.

FIG. 12 is a second schematic partial sectional view of a drive chip pin of a display substrate according to yet another embodiment of the present disclosure.

FIGS. 13A-13H are schematic diagrams of a manufacturing process of a drive chip pin of a display substrate according to another embodiment of the present disclosure.

FIG. 14 is a schematic partial sectional view of a display device according to an embodiment of the present disclosure.

### DETAILED DESCRIPTION

The embodiments of the present disclosure will be described in detail hereinafter with reference to the drawings. Implementations may be implemented in multiple different forms. Those of ordinary skills in the art may easily understand such a fact that implementations and contents may be transformed into one or more forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, an implementation of the present disclosure is not necessarily limited to the size, and a shape and a size of each component in the drawings do not reflect an actual scale. In addition, the accompanying drawings schematically illustrate ideal examples, and an implementation of the present disclosure is not limited to shapes, numerical values, or the like shown in the drawings.

Ordinal numerals such as “first”, “second” and “third” in the present disclosure are set to avoid confusion between constituent elements, but not intended for restriction in quantity. In the present disclosure, “a plurality of/multiple” means two or more than two.

In the present disclosure, for convenience, wordings indicating orientation or positional relationship such as “middle”, “upper”, “lower”, “front”, “rear”, “vertical”, “horizontal”, “top”, “bottom”, “inner” and “outer” are employed to explain positional relationship between the constituent elements with reference to the accompanying drawings, they are employed for ease of description of the specification and simplification of the description only, but do not indicate or imply that the referred device or element must have a particular orientation, or is constructed and operated in a particular orientation, and therefore cannot be construed as limitations on the present disclosure. The positional relationships between the constituent elements are changed as appropriate based on directions according to which the constituent elements are described. Therefore, appropriate replacements based on situations are allowed, which is not limited to the expressions in the specification.

In the present disclosure, the terms “mounting”, “coupling” and “connection” are to be understood broadly, unless otherwise expressly specified and defined. For example, it may be a fixed connection, or a detachable connection, or an integral connection; it may be a mechanical connection or an electrical connection; it may be a direct connection, or an indirect connection through a middleware, or an internal communication between two elements. Those of ordinary skills in the art may understand meanings of the aforementioned terms in the present disclosure according to situations.

In the present disclosure, a transistor refers to an element including at least three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. In the present disclosure, the channel region refers to a region through which a current mainly flows.

In the present disclosure, a first pole may be a drain electrode and a second pole may be a source electrode, or a first pole may be a source electrode and a second pole may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode” are interchangeable in the present disclosure.

In the present disclosure, “electric connection” includes a case where constituent elements are connected through an element with a certain electrical effect. The “element with a certain electrical effect” is not particularly limited as long as electrical signals between the connected constituent elements may be sent and received. Examples of the “element with a certain electrical effect” not only include electrodes and wirings, but also include switching elements such as transistors, resistors, inductors, capacitors, other elements with one or more functions, and the like.

In the present disclosure, “parallel” refers to a state in which an angle formed by two straight lines is above −10° and below 10°, and thus may include a state in which the angle is above −5° and below 5°. In addition, “perpendicular” refers to a state in which an angle formed by two straight lines is above 80° and below 100°, and thus may include a state in which the angle is above 85° and below 95°.

In the present disclosure, “film” and “layer” are interchangeable. For example, a “conductive layer” may be replaced with a “conductive film” sometimes. Similarly, an “insulation film” may be replaced with an “insulation layer” sometimes.

In the present disclosure, “about” means that a boundary is not defined so strictly and numerical values within process and measurement error ranges are allowed.

An embodiment of the present disclosure provides a display substrate. The display substrate includes: a base substrate including a display area and a first bezel area located on one side of the display area; multiple sub-pixels located in the display area; multiple data lines located in the display area, the multiple data lines being electrically connected to the multiple sub-pixels; multiple data line lead lines located in the first bezel area, the multiple data line lead lines being electrically connected to the multiple data lines; and multiple drive chip pins located in the first bezel area. One of the drive chip pins is electrically connected to one of the data line lead lines, and the multiple drive chip pins are located on one side of the multiple data line lead lines away from the base substrate. At least one groove structure is provided on a surface on a side of the drive chip pins away from the base substrate, the at least one groove structure includes a groove bottom and a groove wall connecting the groove bottom, the at least one groove structure has a groove depth in a thickness direction of the display substrate, and the groove depth ranges from 0.40 micron to 0.65 micron.

In a display substrate according to an embodiment of the present disclosure, by defining the groove depth of the groove structure of the drive chip pin in the first bezel area, after the display substrate is assembled into a display device, a component to be installed such as an electrical element may be reliably connected to the first bezel area via the groove structure, thereby avoiding problems such as dark lines and improving the yield rate of the display device.

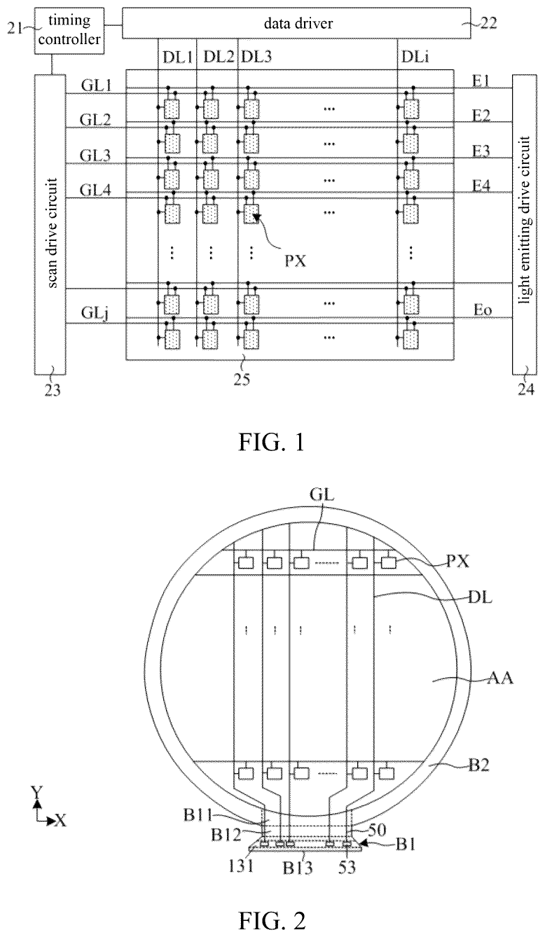

FIG. 1 is a schematic diagram of a structure of a display device according to an embodiment of the present disclosure. As shown in FIG. 1, the display device may include a timing controller 21, a data driver 22, a scan drive circuit 23, a light emitting drive circuit 24, and a sub-pixel array 25. In some examples, the sub-pixel array 25 may include multiple sub-pixels PX arranged regularly. The scan drive circuit 23 may be configured to provide a scan signal to a sub-pixel PX along a scan line. The data driver 22 may be configured to provide a data voltage to a sub-pixel PX along a data line. The light emitting drive circuit 24 may be configured to provide a light emitting control signal to a sub-pixel PX along a light emitting control line. The timing controller 21 may be configured to control the scan drive circuit 23, the light emitting drive circuit 24, and the data driver 22.

In an exemplary embodiment, as shown in FIG. 1, the timing controller 21 may provide a gray scale value and a control signal suitable for a specification of the data driver 22 to the data driver 22. The timing controller 21 may provide a scan clock signal, a scan start signal, and the like suitable for a specification of the scan drive circuit 23 to the scan drive circuit 23. The timing controller 21 may provide the light emitting drive circuit 24 with a light emitting clock signal, a light emitting start signal and the like suitable for a specification of the light emitting drive circuit 24. The data driver 22 may generate a data voltage to be provided to multiple data lines using the gray scale value and the control signal received from the timing controller 21, and the multiple data lines may include data lines DL1 to DLi. For example, the data driver 22 may sample the gray scale value by using a clock signal, and apply a data voltage corresponding to the gray scale value to the data lines DL1 to DLi by taking a sub-pixel row as a unit. The scan drive circuit 23 may generate a scan signal to be provided to multiple scan lines by the scan clock signal, the scan start signal, or the like received from the timing controller 21, and the multiple scan lines may include scan lines GL1 to GLj. For example, the scan drive circuit 23 may provide sequentially a scan signal with an on-level pulse to the scan lines. In some examples, the scan drive circuit 23 may include a shift register and may generate a scan signal by means of sequentially transmitting a scan start signal provided in a form of an on-level pulse to a next-stage circuit under control of a scan clock signal. The light emitting drive circuit 24 may generate a light emitting control signal to be provided to light emitting control lines El to Eo by the light emitting clock signal, the light emitting start signal, and the like received from the timing controller 21. For example, the light emitting drive circuit 24 may provide sequentially a light emitting control signal with an off-level pulse to the light emitting control lines. The light emitting drive circuit 24 may include a shift register, and generate a light emitting control signal by sequentially transmitting a light emitting start signal provided in a form of an off-level pulse to a next-stage circuit under control of the clock signal. Herein, i, j, and o are all natural numbers.

In an exemplary embodiment, the display device may include a display substrate. The scan drive circuit and the light emitting drive circuit may be directly provided on the display substrate. For example, the scan drive circuit may be provided on a left bezel of the display substrate, and the light emitting drive circuit may be provided on a right bezel of the display substrate. Alternatively, the scan drive circuit and the light emitting drive circuit may be provided on both the left bezel and the right bezel of the display substrate. In some examples, the scan drive circuit and the light emitting drive circuit may be formed together with the sub-pixels in a process of forming the sub-pixels.

In an exemplary embodiment, the data driver may be provided on an independent chip or printed circuit board to be connected to the sub-pixel through a signal access pin on the display substrate. For example, the data driver may be made of a chip on glass, a chip on plastics, a chip on film, or the like to form a first bezel provided on the display substrate to be connected to the signal access pin. The timing controller may be provided separately from or integrally with the data driver. However, an embodiment of the present disclosure is not limited thereto. In some examples, the data driver may be directly provided on the display substrate.

FIG. 2 is a schematic planar view of a display substrate according to an embodiment of the present disclosure. As illustrated in FIG. 2, the display substrate may include a display area AA and a peripheral area surrounding the display area AA. The peripheral area may include a first bezel area B1 located on one side of the display area AA, and a second bezel area B2 located on other sides of the display area AA. In an embodiment of the present disclosure, the first bezel area B1 may also be referred to as a bonding area. The second bezel area B2 may be located at least on two sides of the first bezel area B1. By way of example, the first bezel area B1 may be a lower bezel of the display substrate, and the second bezel area B2 may include an upper bezel, a left bezel, and a right bezel of the display substrate. In some examples, the display area AA may be a flat area including multiple sub-pixels PX that form a sub-pixel array, and the multiple sub-pixels PX are configured to display a dynamic picture or a static image. The display area may also be referred to as an effective area. In some examples, the display substrate may be a flexible substrate. Accordingly, the display substrate may be deformable, for example, crimped, bent, folded, or curled.

In an exemplary embodiment, the second bezel area B2 may include a circuit region, a power supply line region, a crack dam region and a cutting region which are arranged sequentially along a direction of the display area AA. The circuit region may be connected to the display area AA, and the circuit region may at least include a gate drive circuit (for example, the gate drive circuit may include multiple cascaded shift registers) and the multiple shift registers may be electrically connected to multiple scan lines in the display area AA. The power supply line region is connected to the circuit region, and the power supply line region may at least include a low-level power supply line. The low-level power supply line may extend along a direction parallel to an edge of the display area and be connected to a cathode in the display area AA. The crack dam region may be connected to the power supply line region, and the crack dam region may at least include multiple cracks provided on a composite insulation layer. The cutting region may be connected to the crack dam region, and the cutting region may at least include cutting grooves provided on the composite insulation layer. The cutting grooves are configured such that a cutting device cuts along the cutting grooves after all film layers of the display substrate are completely manufactured.

In an exemplary embodiment, as shown in FIG. 2, the display area AA may include multiple sub-pixels PX, multiple scan lines GL, and multiple data lines DL. The multiple scan lines GL may extend in a first direction X and the multiple data lines DL may extend in a second direction Y. Orthographic projections of the multiple scan lines GL on the display substrate and orthographic projections of the multiple data lines DL on the display substrate intersect to form multiple sub-pixel regions, and one of the sub-pixels PX is provided in each sub-pixel region. Multiple data lines DL are electrically connected to multiple sub-pixels PX. By way of example, one data line DL is electrically connected to a column of sub-pixels PX. The multiple data lines DL may be configured to provide data signals to the multiple sub-pixels PX. Multiple data lines DL may extend to the first bezel area B1. The multiple scan lines GL are electrically connected to the multiple sub-pixels PX, and the multiple scan lines GL may be configured to provide a gate control signal to the multiple sub-pixels PX. In some examples, the gate control signals may include a scan signal and a light emitting control signal.

In an exemplary embodiment, as shown in FIG. 2, the first direction X may be an extension direction (row direction) of the scan lines GL in the display area AA, and the second direction Y may be an extension direction (column direction) of the data lines DL in the display area AA. The first direction X and the second direction Y may intersect with each other. By way of example, the first direction X and the second direction Y may be perpendicular to each other. In an embodiment of the present disclosure, the first direction X is also a line width direction of the data line DL.

In an exemplary embodiment, as shown in FIG. 2, the first bezel area B1 may include a first sub-area B11, a bent area B12, and a second sub-area B13 in a direction away from the display area AA. Both ends of the first sub-area B11 in the first direction X may be communicated with the second bezel area B2 on the left side and the right side. In an embodiment of the present disclosure, the first sub-area B11 may also be referred to as a first fan-out area, and the first sub-area B11 may be connected to the display area AA.

In an exemplary embodiment, as shown in FIG. 2, the bent area B12 may be connected between the first sub-area B11 and the second sub-area B13. By way of example, the bent area B12 may include a composite insulation layer provided with a groove, and the groove may be configured to bend a portion of the first bezel area B1 to a back surface of the display area AA.

In an exemplary embodiment, a width of the bent area B12 in the second direction Y may range from 0.5 mm to 1.0 mm. By way of example, the width of the bent area B12 in the second direction Y may be 1.0 mm.

In an exemplary embodiment, as shown in FIG. 2, the second sub-area B13 may include multiple pins. The second sub-area B13 may include a circuit arrangement region, a drive chip region 131, and a bonding pin region, which are provided sequentially in a direction away from the display area AA. The circuit arrangement region may at least include an electrostatic discharge circuit and the electrostatic discharge circuit may be configured to prevent electrostatic damage to the display substrate by eliminating static electricity. The drive chip region 131 may be provided for arranging a drive chip (Integrated Circuit, IC), the drive chip region 131 may include multiple drive chip pins 53, and the drive chip may be electrically connected to the data line DL of the display area AA through the drive chip pin 53 and the data line lead line 50. The first bezel area B1 may include multiple data line lead lines 50 and the multiple data line lead lines 50 are electrically connected to multiple data lines DL. By way of example, the data line lead lines 50 and the data lines DL are connected in one-to-one correspondence. The drive chip may be configured to generate a signal required for driving sub-pixels and to provide the drive signal to the data lines of the display area. For example, the drive signal may be a data signal that drives the sub-pixels to emit light. The bonding pin region may include multiple bonding pins, the bonding pins may be configured to be bonded to at least one corresponding circuit board (for example, a Flexible Printed Circuit (FPC)). The drive chip pin 53 in the drive chip region 131 may be electrically connected to the bonding pin in the bonding pin region through a pin connection line. In an exemplary embodiment, one pixel unit of the display area AA may include multiple sub-pixels. By way of example, a pixel unit may include three sub-pixels, and the three sub-pixels may be respectively a red sub-pixel, a green sub-pixel, and a blue sub-pixel. However, an embodiment of the present disclosure is not limited thereto. In some examples, one pixel unit may include four sub-pixels, and the four sub-pixels are a red sub-pixel, a green sub-pixel, a blue sub-pixel, and a white sub-pixel respectively.

In some exemplary embodiments, a shape of the sub-pixel may be a rectangle, a rhombus, a pentagon, or a hexagon. When one pixel unit includes three sub-pixels, the three sub-pixels may be arranged side by side horizontally, side by side vertically, or arranged in a manner of a Chinese character “(”. When one pixel unit includes four sub-pixels, the four sub-pixels may be arranged side by side horizontally, side by side vertically, or in a manner to form a square. However, an embodiment of the present disclosure is not limited thereto.

In an exemplary embodiment, one sub-pixel may include a pixel circuit and a light emitting element electrically connected to the pixel circuit. The pixel circuit may include multiple transistors and at least one capacitor. For example, the pixel circuit may have a 3T1C, 4T1C, 5T1C, 5T2C, 6T1C, 7T1C, or 8T1C structure. In the aforementioned circuit structures, T refers to a thin film transistor, C refers to a capacitor, a digit before T represents a quantity of thin film transistors in the circuit, and a digit before C represents a quantity of capacitors in the circuit. In some examples, the multiple transistors in the pixel circuit may be P-type transistors or may be N-type transistors. Usage of same type of transistors in the pixel circuit may simplify a process flow, reduce a process difficulty of the display substrate, and improve a yield of a product. In some other examples, the multiple transistors in the pixel circuit may include a P-type transistor and an N-type transistor.

In an exemplary embodiment, for the multiple transistors in the pixel circuit, a low temperature poly-silicon thin film transistor may be adopted, or an oxide thin film transistor may be adopted, or a low temperature poly-silicon thin film transistor and an oxide thin film transistor may be adopted. An active layer of a low temperature poly-silicon thin film transistor is made of Low Temperature Poly-Silicon (LTPS), and an active layer of an oxide thin film transistor is made of an oxide semiconductor (Oxide). The low temperature poly-silicon thin film transistor has advantages such as high migration rate and fast charging, and the oxide thin film transistor has advantages such as low leakage current. The low temperature poly-silicon thin film transistor and the oxide thin film transistor are integrated on one display substrate, that is, an LTPS+Oxide (LTPO) display substrate, advantages of both the low temperature poly-silicon thin film transistor and the oxide thin film transistor may be utilized, so that low-frequency drive can be achieved, power consumption can be reduced, and display quality can be improved.

In an exemplary embodiment, the light emitting element may be any one of a Light Emitting Diode (LED), an Organic Light Emitting Diode (OLED), a Quantum Dot Light Emitting Diode (QLED), a micro LED (including a mini-LED or a micro-LED), and the like. For example, the light emitting element may be an OLED, and the light emitting element may emit red light, green light, blue light, or white light, or the like under driving of a pixel circuit corresponding to the light emitting element. A color of light emitted from the light emitting element may be determined as required. In some examples, the light emitting element may include an anode, a cathode, and an organic light emitting layer located between the anode and the cathode. The anode of the light emitting element may be electrically connected to a corresponding pixel circuit. However, an embodiment of the present disclosure is not limited thereto.

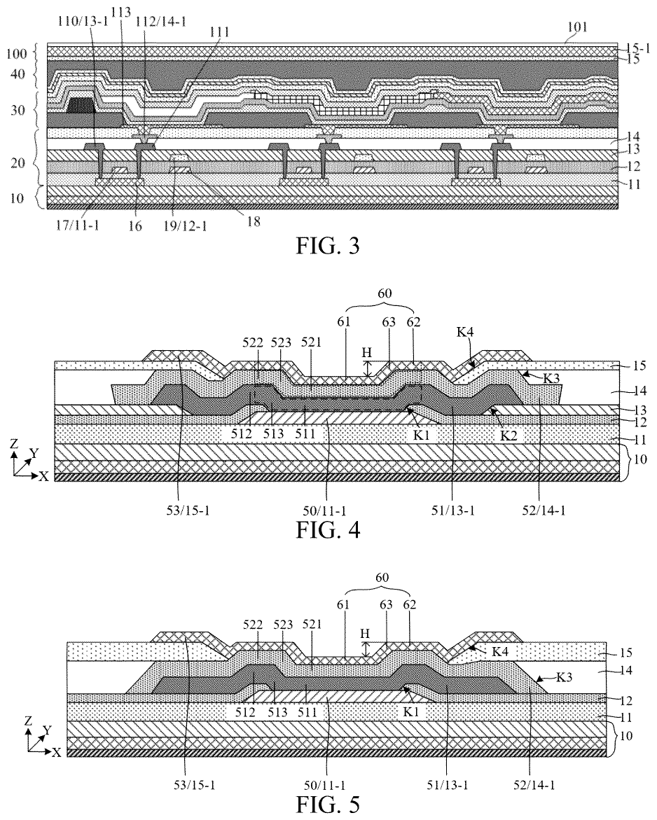

FIG. 3 is a schematic partial sectional view of a display area of a display substrate according to an embodiment of the present disclosure. As shown in FIG. 3, in a direction perpendicular to the display substrate, the display area of the display substrate may include a base substrate 10, and a circuit structure layer 20, a light emitting structure layer 30, an encapsulation layer 40, and a touch structure layer 100 that are provided sequentially on the base substrate 10. The touch structure layer 100 may include an over coating (OC) 101, a touch layer, and a touch insulation layer provided in a stack.

In an exemplary embodiment, the base substrate 10 may be a flexible base substrate, or may be a rigid base substrate. The rigid base substrate may be, but is not limited to, one or more of glass and quartz. The flexible base substrate may be, but is not limited to, one or more of polyethylene terephthalate, ethylene terephthalate, polyether ether ketone, polystyrene, polycarbonate, polyarylate, polyarylester, polyimide, polyvinyl chloride, polyethylene, textile fibers, or the like.

In an exemplary embodiment, the base substrate 10 may be a composite film layer. By way of example, as shown in FIG. 3, the base substrate 10 may be a composite film layer of three film layers. By way of example, the base substrate 10 may include a first inorganic sublayer, an organic layer, and a second inorganic sublayer that are stacked sequentially.

In an exemplary embodiment, as shown in FIG. 3, the circuit structure layer 20 may include multiple transistors and a storage capacitor constituting a pixel circuit. In FIG. 3, it is taken as an example that each sub-pixel includes only one transistor and one storage capacitor. The circuit structure layer 20 may include a semiconductor layer provided on one side of the base substrate 10, a first insulation layer 11 covering the semiconductor layer, a first conductive layer 11-1 provided on the first insulation layer 11, a second insulation layer 12 covering the first conductive layer 11-1, a second conductive layer 12-1 provided on the second insulation layer 12, a third insulation layer 13 covering the second conductive layer 12-1, a third conductive layer 13-1 provided on the third insulation layer 13, and a fourth conductive layer 14-1 and a fourth insulation layer 14 provided on a side of third conductive layer 13-1 away from the base substrate 10. The semiconductor layer may include an active layer 16 of the transistor. The first conductive layer 11-1 may include a gate 17 of the transistor and a first capacitance electrode 18 of the storage capacitor. The second conductive layer 12-1 may include a second capacitance electrode 19 of the storage capacitor. The third conductive layer 13-1 may include a source electrode 110, a drain electrode 111, and a data line of the transistor. The fourth conductive layer 14-1 may include a pixel connection electrode 112 and the pixel connection electrode 112 may be configured to be connected to an anode 113 of the light emitting element. In an embodiment of the present disclosure, in the display area of the display substrate, the first conductive layer may also be referred to as a first gate metal layer, the second conductive layer may also be referred to as a second gate metal layer, the third conductive layer may also be referred to as a first source-drain metal layer, and the fourth conductive layer may also be referred to as a second source-drain metal layer. The first insulation layer 11 may also be referred to as a first gate insulation layer (GI1), the second insulation layer 12 may also be referred to as a second gate insulation layer (GI2), the third insulation layer 13 may also be referred to as an interlayer insulation layer (ILD), and the fourth insulation layer 14 may also be referred to as a first planarization layer (PLN1).

In an exemplary embodiment, a material of the conductive layer may be a metal material, such as any one or more of silver (Ag), copper (Cu), aluminum (Al), titanium (Ti) and molybdenum (Mo), or an alloy material of the aforementioned metals, such as aluminum neodymium alloy (AlNd) or molybdenum niobium alloy (MoNb), and may be a single-layered structure or a multi-layered composite structure, for example Ti/Al/Ti.

In an exemplary embodiment, the material of the conductive layer may be a transparent conductive material such as indium tin oxide (ITO) or indium zinc oxide (IZO).

In an exemplary embodiment, a material of the insulation layer may include any one or more of an epoxy resin, a phenol resin, a urea-formaldehyde resin, a melamine-formaldehyde resin, a furan resin, a silicone resin, a polyester resin, a polyamide resin, an acrylic resin, a polyurethane, a vinyl resin, a hydrocarbon resin, a polyether resin, and the like.

In an exemplary embodiment, the material of the insulation layer may include any one or more of silicon oxide (SiOx), silicon nitride (SiNx), silicon oxynitride (SiOxNy), and the like, and may be a single layer, a multilayer layer, or a composite layer.

In an exemplary embodiment, as shown in FIG. 3, the light emitting structure layer 30 may include an anode layer, a pixel definition layer, an organic light emitting layer, and a cathode. The anode layer may include an anode 113 of the light emitting element and the anode 113 is electrically connected to the pixel connection electrode 112. The pixel definition layer is provided with a pixel opening, the pixel opening exposes at least a portion of a surface of the anode 113, and the organic light emitting layer is at least partially provided in the pixel opening. The organic light emitting layer is connected to the anode 113, the cathode of the light emitting element is provided on the organic light emitting layer, the cathode is connected to the organic light emitting layer, and the organic light emitting layer emits light of a corresponding color under driving of the anode 113 and the cathode.

In an exemplary embodiment, the encapsulation layer 40 may include two or more film layers. By way of example, the encapsulation layer 40 may include a first encapsulation layer, a second encapsulation layer, and a third encapsulation layer that are stacked, the first encapsulation layer and the third encapsulation layer may be made of an inorganic material, the second encapsulation layer may be made of an organic material, and the second encapsulation layer is provided between the first encapsulation layer and the third encapsulation layer to ensure that external water vapor cannot enter the light emitting structure layer 30.

FIG. 4 is a first schematic partial sectional view of a drive chip pin of a display substrate according to an embodiment of the present disclosure. As shown in FIG. 4, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second insulation layer 12 located on a side of the first conductive layer 11-1 away from the base substrate 10, a third insulation layer 13 located on a side of the second insulation layer 12 away from the base substrate 10, a third conductive layer 13-1 located on a side of the third insulation layer 13 away from the base substrate 10, a fourth conductive layer 14-1 located on a side of the third conductive layer 13-1 away from the base substrate 10, a fourth insulation layer 14 located on a side of the fourth conductive layer 14-1 away from the base substrate 10, a fifth insulation layer 15 located on a side of the fourth conductive layer 14-1 away from the base substrate 10, and a fifth conductive layer 15-1 located on a side of the fifth insulation layer 15 away from the base substrate 10. As shown in FIG. 4, in an embodiment of the present disclosure, a thickness direction of the display substrate is defined as a third direction, and the third direction is marked as Z. In an embodiment of the present disclosure, the first direction X, the second direction Y, and the third direction Z may be perpendicular to each other in pairs.

In an embodiment of the present disclosure, in the first bezel area of the display substrate, the conductive layer including the data line lead line may also be referred to as a first metal layer, the third conductive layer 13-1 may also be referred to as a second metal layer, the fourth conductive layer 14-1 may also be referred to as a third metal layer, and the fifth conductive layer 15-1 may also be referred to as a fourth metal layer. In an embodiment of the present disclosure, a label of a film layer shared by the first bezel area and the display area is the same, for example, the first insulation layer of the first bezel area and the first insulation layer of the display are both the first insulation layer 11, and the second insulation layer of the first bezel area and the second insulation layer of the display area are both the second insulation layer 12. In an embodiment of the present disclosure, the fifth conductive layer 15-1 located in the display area may also be referred to as a touch layer, and the fifth insulation layer 15 may also be referred to as a touch insulation layer. In an exemplary embodiment, the second insulation layer 12 located on the first bezel area may also be referred to as a first inorganic layer, and the third insulation layer 13 may also be referred to as a second inorganic layer.

As shown in FIG. 4, the first conductive layer 11-1 of the first bezel area of the display substrate may include at least one data line lead line 50. By way of example, multiple data line lead lines 50 may be arranged at intervals in the first direction X and extend in the second direction Y. In an embodiment of the present disclosure, the first direction is also a line width direction of the data line lead line 50. As shown in FIG. 4, only one data line lead line 50 is illustrated as an example, and the data line lead line 50 extending in the second direction Y is taken as an example. In the first bezel area of the display substrate, the third conductive layer 13-1 may include at least one first connection electrode 51, the fourth conductive layer 14-1 may include at least one second connection electrode 52, and the fifth conductive layer 15-1 may include at least one drive chip pin 53, and the drive chip pin 53 is connected to the data line lead line 50 via the second connection electrode 52 and the first connection electrode 51, so that signal transmission may be realized.

In an exemplary embodiment, as shown in FIG. 4, the third conductive layer 13-1 of the first bezel area of the display substrate may include at least one first connection electrode 51. A portion of the first connection electrode 51 is in contact and connected with a portion of the data line lead line 50 through vias located in the second insulation layer 12 and the third insulation layer 13. As shown in FIG. 4, the second insulation layer 12 may be provided with at least one first via K1, the first via K1 penetrates the second insulation layer 12 in the thickness direction of the display substrate and exposes a portion of a surface on a side of the data line lead line 50 away from the base substrate 10. An orthographic projection of the data line lead line 50 on the display substrate may include an orthographic projection of the first via K1 on the display substrate, the second insulation layer 12 may form a protection for an edge of the data line lead line 50, which may prevent the erosion of the data line lead line by water, oxygen and the like, and may prolong the service life of the display substrate.

In an exemplary embodiment, as shown in FIG. 4, the third insulation layer 13 may be provided with at least one second via K2, and the second via K2 penetrates the third insulation layer 13 in the thickness direction of the display substrate and exposes a portion of a surface on a side of the second insulation layer 12 away from the base substrate 10. An orthographic projection of the second via K2 on the display substrate may include an orthographic projection of the first via K1 on the display substrate, and the orthographic projection of the second via K2 on the display substrate is larger than the orthographic projection of the first via K1 on the display substrate. In the first direction X, the orthographic projection of the second via K2 on the display substrate may include the orthographic projection of the data line lead line 50 on the display substrate. By way of example, in the first direction X, the orthographic projection of the second via K2 on the display substrate may be larger than the orthographic projection of the data line lead line 50 on the display substrate. By limiting the relative relationship between an aperture of the second via and an aperture of the first via, a drop of the first connection electrode in the thickness direction of the display substrate may be reduced, so that a component (for example, a drive chip) and the drive chip pin in the first bezel area may be conductively connected in the subsequent process, the problem of the dummy connection may be avoided, the yield rate of the display substrate may be improved, and the reliability of the display substrate may be improved.

In an exemplary embodiment, as shown in FIG. 4, at least a portion of the first connection electrode 51 may be located within the first via K1 and the second via K2. A portion of the first connection electrode 51 may be in contact and connected with a portion of a surface on a side of the data line lead line 50 away from the base substrate 10, and a portion of the first connection electrode 51 may be in contact and connected with a portion of a surface on a side of the second insulation layer 12 away from the base substrate 10, and a portion of the first connection electrode 51 may be in contact and connected with a portion of a surface on a side of the third insulation layer 13 away from the base substrate 10. As shown in FIG. 4, an orthographic projection of the first connection electrode 51 on the display substrate may include the orthographic projection of the second via K2 on the display substrate.

In an exemplary embodiment, as shown in FIG. 4, the fourth insulation layer 14 may be provided with at least one third via K3, and the third via K3 penetrates the fourth insulation layer 14 in the thickness direction of the display substrate.

In an exemplary embodiment, as shown in FIG. 4, the fourth conductive layer 14-1 may include at least one second connection electrode 52, a portion of the second connection electrode 52 may be located in the third via K3, and an orthographic projection of the fourth insulation layer 14 on the display substrate may include an edge of an orthographic projection of the second connection electrode 52 on the display substrate. The second connection electrode 52 is in contact and connected with the first connection electrode 51 and an orthographic projection of the second connection electrode 52 on the display substrate may include an orthographic projection of the first connection electrode 51 on the display substrate. By way of example, the orthographic projection of the second connection electrode 52 on the display substrate may be larger than the orthographic projection of the first connection electrode 51 on the display substrate.

In an exemplary embodiment, as shown in FIG. 4, the fifth insulation layer 15 may be provided with at least one fourth via K4, and the fourth via K4 penetrates the fifth insulation layer 15 in the thickness direction of the display substrate, and exposes a portion of a surface on a side of the second connection electrode 52 away from the base substrate 10. An orthographic projection of the fourth via K4 on the display substrate may be located within a range of the orthographic projection of the second connection electrode 52 on the display substrate.

In an exemplary embodiment, as shown in FIG. 4, the fifth conductive layer 15-1 may include at least one drive chip pin 53, and at least a portion of the drive chip pin 53 may be located in the fourth via K4. By way of example, an orthographic projection of the drive chip pin 53 on the display substrate may include the orthographic projection of the fourth via K4 on the display substrate.

In an exemplary embodiment, as shown in FIG. 4, the drive chip pin 53 has a groove structure 60, and the groove structure 60 is recessed toward the base substrate 10. The groove structure 60 is configured to accommodate a conductive adhesive, for example an anisotropic conductive adhesive, to enable an electrical connection between a component to be installed and the data line lead line 50. By way of example, the component to be installed may be a drive chip (Integrated Circuit, IC). The drive chip may transmit a signal to the data line lead line 50 through the drive chip pin 53, and the data line lead line 50 transmits the signal to the data line.

In an exemplary embodiment, as shown in FIG. 4, the groove structure 60 has a groove bottom 61, a groove top 62, and a groove wall 63. The groove bottom 61 and the groove top 62 may be provided oppositely to each other in the thickness direction of the display substrate, and the groove bottom 61 is closer to the base substrate 10 than the groove top 62. The groove wall 63 may extend in the thickness direction of the display substrate, the groove wall 63 has a first end and a second end provided oppositely to each other, the first end of the groove wall 63 may be connected to the groove bottom 61, and the second end of the groove wall 63 may extend in a direction away from the base substrate 10. The groove top 62 has a first end and a second end provided oppositely to each other, the first end of the groove top 62 may be connected to the second end of the groove wall 63, and the second end of the groove top 62 extends in a direction away from the first end. An orthographic projection of the groove top 62 on the display substrate may be annular. By way of example, the orthographic projection of the groove top 62 on the display substrate may be circular annular, rectangular annular, or the like.

In an exemplary embodiment, as shown in FIG. 4, there is a distance H between the groove bottom 61 and the groove top 62 in the thickness direction of the display substrate, and the distance H may range from 0.55 micron to 0.65 micron. By way of example, the distance H may be 0.63 micron, or the distance H may be 0.60 micron, or the distance H may be 0.55 micron. In an embodiment of the present disclosure, the distance H may also be referred to as a groove depth of the groove structure 60. In a display substrate provided by an embodiment of the present disclosure, the groove depth of the groove structure is limited to less than 0.65 micron, so that the component to be installed (for example, the drive chip) that is to be subsequently installed may be firmly connected to the data line lead line via the groove structure, the problem of the dummy connection may be avoided, and the use reliability of the display device may be improved.

In an exemplary embodiment, as shown in FIG. 4, the second connection electrode 52 has a second sub-groove. The second sub-groove has a second groove bottom 521, a second groove top 522, and a second groove wall 523. The second groove bottom 521 and the second groove top 522 may be provided oppositely to each other in the thickness direction of the display substrate and the second groove bottom 521 is closer to the base substrate 10 than the second groove top 522. The second groove wall 523 may extend in the thickness direction of the display substrate, the second groove wall 523 has a first end and a second end provided oppositely to each other, the first end of the second groove wall 523 may be connected to the second groove bottom 521, and the second end of the second groove wall 523 may extend in a direction away from the base substrate 10. The second groove top 522 has a first end and a second end provided oppositely to each other, the first end of the second groove top 522 may be connected to the second end of the second groove wall 523, and the second end of the second groove top 522 extends in a direction away from the first end. An orthographic projection of the second groove top 522 on the display substrate may be annular, for example, the orthographic projection of the second groove top 522 on the display substrate may be circular annular, rectangular annular, or the like.

In an exemplary embodiment, as shown in FIG. 4, the groove top 62 is in contact and connected with the second groove top 522. Compared with a structure in which an insulation layer is provided between the groove top 62 and the second groove top 522, the groove depth of the groove structure 60 can be reduced by a contact connection between the groove top 62 and the second groove top 522, which is beneficial to a fixation of the component to be installed (for example, the drive chip), and a dummy connection of the component to be installed may be avoided.

In an exemplary embodiment, as shown in FIG. 4, the first connection electrode 51 has a first sub-groove. The first sub-groove has a first groove bottom 511, a first groove top 512, and a first groove wall 513. The first groove bottom 511 and the first groove top 512 may be provided oppositely to each other in the thickness direction of the display substrate and the first groove bottom 511 is closer to the base substrate 10 than the first groove top 512. The first groove wall 513 may extend in the thickness direction of the display substrate, the first groove wall 513 has a first end and a second end provided oppositely to each other, the first end of the first groove wall 513 may be connected to the first groove bottom 511, and the second end of the first groove wall 513 may extend in a direction away from the base substrate 10. The first groove top 512 has a first end and a second end provided oppositely to each other, the first end of the first groove top 512 may be connected to the second end of the first groove wall 513, and the second end of the first groove top 512 extends in a direction away from the first end. An orthographic projection of the first groove top 512 on the display substrate may be annular, for example, the orthographic projection of the first groove top 512 on the display substrate may be circular annular, rectangular annular, or the like.

In an exemplary embodiment, as shown in FIG. 4, the first groove top 512 is in contact and connected with the second groove top 522. Compared with a structure in which an insulation layer is provided between the first groove top 512 and the second groove top 522, the groove depth of the groove structure 60 can be reduced by a contact connection between the first groove top 512 and the second groove top 522, which is beneficial to the fixation of the component to be installed (for example, the drive chip), and a dummy connection of the component to be installed may be avoided.

FIG. 5 is a second schematic partial sectional view of a drive chip pin of a display substrate according to an embodiment of the present disclosure. As shown in FIG. 5, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second insulation layer 12 located on a side of the first conductive layer 11-1 away from the base substrate 10, a third conductive layer 13-1 located on a side of the second insulation layer 12 away from the base substrate 10, a fourth conductive layer 14-1 located on a side of the third conductive layer 13-1 away from the base substrate 10, a fourth insulation layer 14 located on a side of the second insulation layer 12 away from the base substrate 10, a fifth insulation layer 15 located on a side of the fourth conductive layer 14-1 away from the base substrate 10, and a fifth conductive layer 15-1 located on a side of the fifth insulation layer 15 away from the base substrate 10. A main body structure of the drive chip pin shown in FIG. 5 is substantially the same as a main body structure of the aforementioned drive chip pin shown in FIG. 4, except that the third insulation layer does not extend to the first bezel area, which may reduce a quantity of film layers in the first bezel area, and a film layer structure in the first bezel area may be optimized.

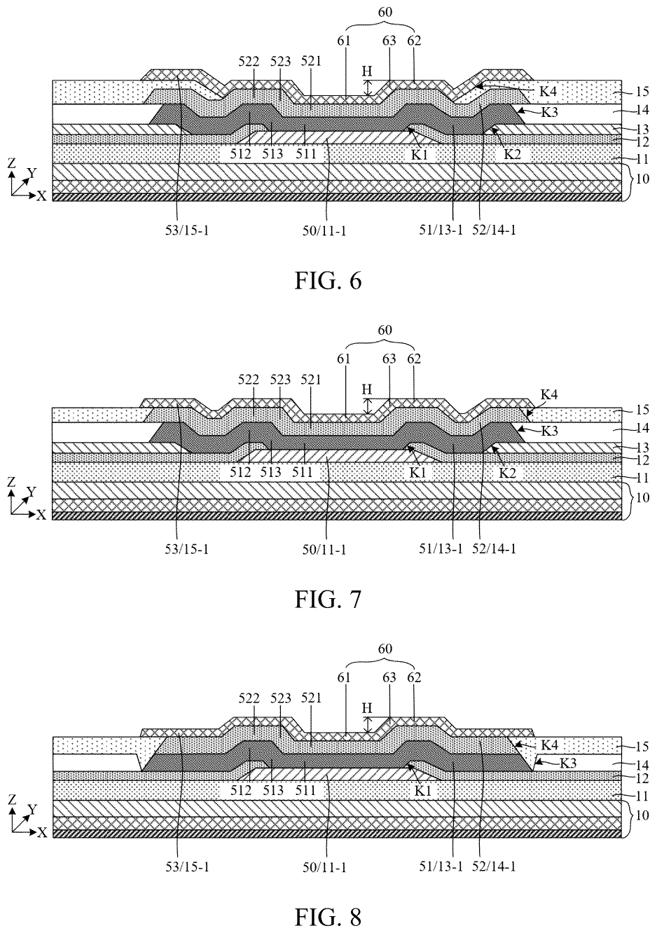

FIG. 6 is a third schematic partial sectional view of a drive chip pin of a display substrate according to an embodiment of the present disclosure. As shown in FIG. 6, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second insulation layer 12 located on a side of the first conductive layer 11-1 away from the base substrate 10, a third insulation layer 13 located on a side of the second insulation layer 12 away from the base substrate 10, a third conductive layer 13-1 located on a side of the third insulation layer 13 away from the base substrate 10, a fourth insulation layer 14 located on a side of the third insulation layer 13 away from the base substrate 10, a fourth conductive layer 14-1 located on a side of the fourth insulation layer 14 away from the base substrate 10, a fifth insulation layer 15 located on a side of the fourth conductive layer 14-1 away from the base substrate 10, and a fifth conductive layer 15-1 located on a side of the fifth insulation layer 15 away from the base substrate 10. A main body structure of the drive chip pin shown in FIG. 6 is substantially the same as a main body structure of the aforementioned drive chip pin shown in FIG. 4, except that a portion that is close to the fourth insulation layer 14 of a surface on a side of the third conductive layer 13-1 away from the base substrate 10 is substantially flush with a portion that is close to the third conductive layer 13-1 of a surface on a side of the fourth insulation layer 14 away from the base substrate 10, and the fourth conductive layer 14-1 is located on a side of the fourth insulation layer 14 away from the base substrate 10, which may simplify the manufacturing process of the third via K3 and reduce the manufacturing cost of the display substrate.

FIG. 7 is a fourth schematic partial sectional view of a drive chip pin of a display substrate according to an embodiment of the present disclosure. As shown in FIG. 7, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second insulation layer 12 located on a side of the first conductive layer 11-1 away from the base substrate 10, a third insulation layer 13 located on a side of the second insulation layer 12 away from the base substrate 10, a third conductive layer 13-1 located on a side of the third insulation layer 13 away from the base substrate 10, a fourth insulation layer 14 located on a side of the third insulation layer 13 away from the base substrate 10, a fourth conductive layer 14-1 located on a side of the fourth insulation layer 14 away from the base substrate 10, a fifth insulation layer 15 located on a side of the fourth insulation layer 14 away from the base substrate 10, and a fifth conductive layer 15-1 located on a side of the fifth insulation layer 15 away from the base substrate 10. A main body structure of the drive chip pin shown in FIG. 7 is substantially the same as a main body structure of the aforementioned drive chip pin shown in FIG. 6, except that a portion that is close to the fifth insulation layer 15 of a surface on a side of the fourth conductive layer 14-1 away from the base substrate 10 is substantially flush with a portion that is close to the fourth conductive layer 14-1 of a surface on a side of the fifth insulation layer 15 away from the base substrate 10, which may simplify the manufacturing process of the fourth via K4 and reduce the manufacturing cost of the display substrate.

FIG. 8 is a fifth schematic partial sectional view of a drive chip pin of a display substrate according to an embodiment of the present disclosure. As shown in FIG. 8, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second insulation layer 12 located on a side of the first conductive layer 11-1 away from the base substrate 10, a third conductive layer 13-1 located on a side of the second insulation layer 12 away from the base substrate 10, a fourth insulation layer 14 located on a side of the second insulation layer 12 away from the base substrate 10, a fourth conductive layer 14-1 located on a side of the fourth insulation layer 14 away from the base substrate 10, a fifth insulation layer 15 located on a side of the fourth insulation layer 14 away from the base substrate 10, and a fifth conductive layer 15-1 located on a side of the fifth insulation layer 15 away from the base substrate 10. A main body structure of the drive chip pin shown in FIG. 8 is substantially the same as a main body structure of the aforementioned drive chip pin shown in FIG. 7, except that the third insulation layer does not extend to the first bezel area, which may simplify a film layer structure in the first bezel area.

Exemplary description is made below through a manufacturing process of a display substrate. A “patterning process” mentioned in the present disclosure includes photoresist coating, mask exposure, development, etching, photoresist stripping, and the like for a metal material, an inorganic material, or a transparent conductive material, and includes organic material coating, mask exposure, development, and the like for an organic material. Deposition may be any one or more of sputtering, evaporation, and chemical vapor deposition, coating may be any one or more of spray coating, spin coating, and inkjet printing, and etching may be any one or more of dry etching and wet etching, the present disclosure is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided in a same layer” in the present disclosure means that A and B are formed simultaneously through a same patterning process, and a “thickness” of a film layer is a dimension of the film layer in a direction perpendicular to a display substrate. In an exemplary embodiment of the present disclosure, “an orthographic projection of B being within a range of an orthographic projection of A” or “an orthographic projection of A containing an orthographic projection of B” means that a boundary of the orthographic projection of B falls within a range of a boundary of the orthographic projection of A, or the boundary of the orthographic projection of A overlaps with the boundary of the orthographic projection of B.

Taking a structure of the drive chip pin of the display substrate shown in FIG. 4 as an example, the manufacturing process of the drive chip pin of the display substrate may include the following steps (11) to (17).

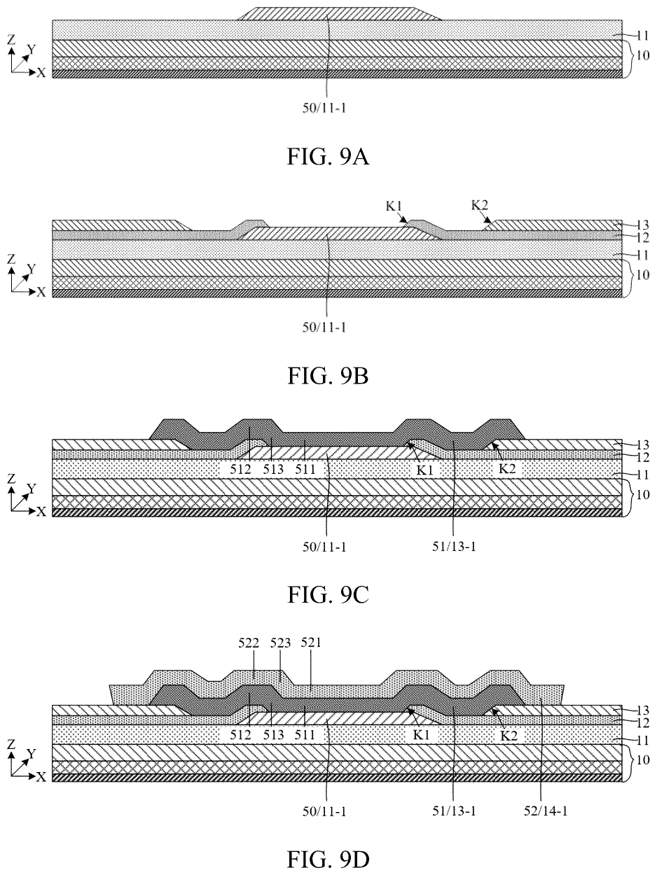

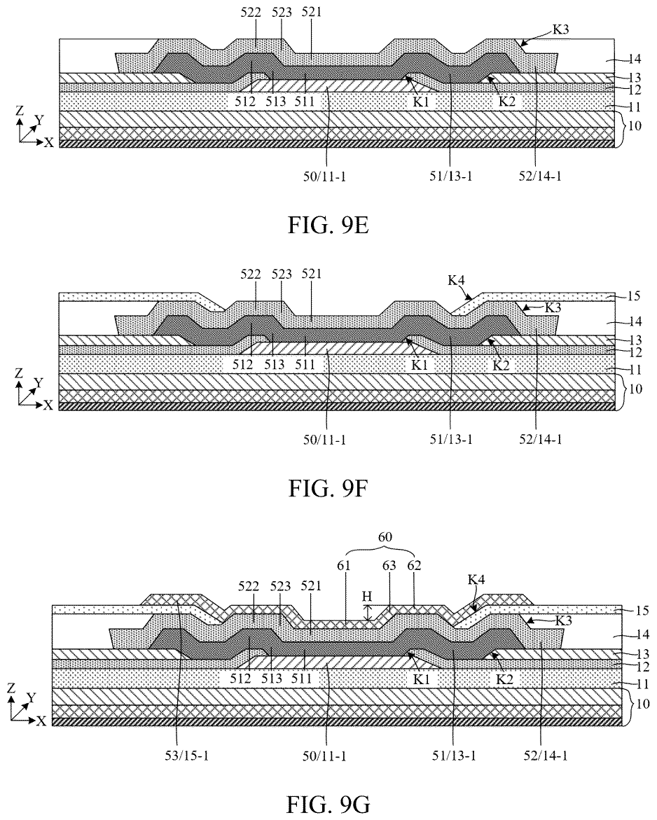

(11) Forming a pattern of a first conductive layer. Forming the pattern of the first conductive layer may include sequentially depositing a first insulation thin film and a first conductive thin film on a side of a base substrate 10, and patterning the first conductive thin film by a patterning process to form a first insulation layer 11 and the pattern of the first conductive layer located on a side of the first insulation layer 11 on a side of the base substrate 10. The first conductive layer 11-1 may at least include one data line lead line 50, as shown in FIG. 9A.

(12) Forming a pattern of a third insulation layer. Forming the pattern of the third insulation layer may include sequentially depositing a second insulation thin film and a third insulation thin film on a side of the base substrate 10 on which the aforementioned pattern is formed, and patterning the third insulation thin film by a patterning process of a Half Tone Mask to form a pattern of a second insulation layer on a side of the first conductive layer 11-1 and the pattern of the third insulation layer on a side of the pattern of the second insulation layer, as shown in FIG. 9B.

As shown in FIG. 9B, the second insulation layer 12 may have at least one first via K1, the first via K1 penetrates the second insulation layer 12 in a thickness direction of the display substrate and exposes a portion of a surface on a side of the data line lead line 50 away from the base substrate 10. An orthographic projection of the data line lead line 50 on the display substrate may include an orthographic projection of the first via K1 on the display substrate and the second insulation layer 12 may form a protection for an edge of the data line lead line 50. The first via K1 may be a circular hole, an elliptical hole, a rectangular hole, a hexagonal hole, or the Like.

As shown in FIG. 9B, the third insulation layer 13 may have at least one second via K2, the second via K2 penetrates the third insulation layer 13 in the thickness direction of the display substrate and exposes a portion of a surface on a side of the second insulation layer 12 away from the base substrate 10. An orthographic projection of the second via K2 on the display substrate may include an orthographic projection of the first via K1 on the display substrate and the orthographic projection of the second via K2 on the display substrate is larger than the orthographic projection of the first via K1 on the display substrate. In a first direction X, the orthographic projection of the second via K2 on the display substrate may include the orthographic projection of the data line lead line 50 on the display substrate. By way of example, in the first direction X, the orthographic projection of the second via K2 on the display substrate may be larger than the orthographic projection of the data line lead line 50 on the display substrate. By limiting the relative relationship between an aperture of the second via and an aperture of the first via, a drop of the first connection electrode to be formed subsequently in the thickness direction of the display substrate may be reduced, so that a component to be installed (for example, a drive chip) and a drive chip pin in a first bezel area may be conductively connected in the subsequent process, and the problem of the dummy connection may be avoided.

(13) Forming a pattern of a third conductive layer. Forming the pattern of the third conductive layer may include depositing a third conductive thin film on a side of the base substrate 10 on which the aforementioned patterns are formed, and patterning the third conductive thin film by a patterning process to form the pattern of the third conductive layer on a side of the third insulation layer 13, as shown in FIG. 9C. The third conductive layer 13-1 may at least include one first connection electrode 51.

As shown in FIG. 9C, at least a portion of the first connection electrode 51 may be located in the first via K1 and the second via K2. The first connection electrode 51 has a first sub-groove. The first sub-groove has a first groove bottom 511, a first groove top 512, and a first groove wall 513. The first groove bottom 511 and the first groove top 512 may be provided oppositely to each other in the thickness direction of the display substrate and the first groove bottom 511 is closer to the base substrate 10 than the first groove top 512. The first groove wall 513 may extend in the thickness direction of the display substrate, the first groove wall 513 has a first end and a second end provided oppositely to each other, the first end of the first groove wall 513 may be connected to the first groove bottom 511, and the second end of the first groove wall 513 may extend in a direction away from the base substrate 10. The first groove top 512 has a first end and a second end provided oppositely to each other, the first end of the first groove top 512 may be connected to the second end of the first groove wall 513, the second end of the first groove top 512 extends in a direction away from the first end, and an orthographic projection of the first groove top 512 on the display substrate may be annular.

As shown in FIG. 9C, the first groove top 512 may be in contact with a surface on a side of the second insulation layer 12 away from the base substrate 10. As described above, by limiting the relative relationship between an aperture of the second via K2 and an aperture of the first via K1, a distance between the first groove top 512 and the first groove bottom 511 in the thickness direction of the display substrate may be reduced, and the groove depth of the groove structure to be formed subsequently may be reduced.

(14) Forming a pattern of a fourth conductive layer. Forming the pattern of the fourth conductive layer may include depositing a fourth conductive thin film on a side of the base substrate 10 on which the aforementioned patterns are formed, and patterning the fourth conductive thin film by a patterning process to form the pattern of the fourth conductive layer on a side of the third conductive layer 13-1, as shown in FIG. 9D.

As shown in FIG. 9D, the fourth conductive layer 14-1 may at least include one second connection electrode 52. The second connection electrode 52 has a second sub-groove. The second sub-groove has a second groove bottom 521, a second groove top 522, and a second groove wall 523. The second groove bottom 521 and the second groove top 522 may be provided oppositely to each other in the thickness direction of the display substrate and the second groove bottom 521 is closer to the base substrate 10 than the second groove top 522. The second groove wall 523 may extend in the thickness direction of the display substrate, the second groove wall 523 has a first end and a second end provided oppositely to each other, the first end of the second groove wall 523 may be connected to the second groove bottom 521, and the second end of the second groove wall 523 may extend in a direction away from the base substrate 10. The second groove top 522 has a first end and a second end provided oppositely to each other, the first end of the second groove top 522 may be connected to the second end of the second groove wall 523, the second end of the second groove top 522 extends in a direction away from the first end, and an orthographic projection of the second groove top 522 on the display substrate may be annular.

As shown in FIG. 9D, the second groove top 522 may be in contact and connected with the first groove top 512, which may reduce the groove depth of the groove structure to be formed subsequently. In this way, the dummy connection between the component to be installed (for example, the drive chip) and the data line lead line 50 is avoided, and the use reliability of the display substrate may be improved.

(15) Forming a pattern of a fourth insulation layer. Forming the pattern of the fourth insulation layer may include depositing a fourth insulation thin film on a side of the base substrate 10 on which the aforementioned patterns are formed, and patterning the fourth insulation thin film by a patterning process to form the pattern of the fourth insulation layer on a side of the fourth conductive layer 14-1, as shown in FIG. 9E.

As shown in FIG. 9E, the fourth insulation layer 14 has at least one third via K3, and the third via K3 exposes a portion of a surface on a side of the second connection electrode 52 away from the base substrate 10. The fourth insulation layer 14 may form a protection for an edge of the second connection electrode 52 and the water-oxygen resistance of the second connection electrode may be improved.

(16) Forming a pattern of a fifth insulation layer. Forming the pattern of the fifth insulation layer may include depositing a fifth insulation thin film on a side of the base substrate 10 on which the aforementioned patterns are formed, and patterning the fifth insulation thin film by a patterning process to form the pattern of the fifth insulation layer located on a side of the fourth conductive layer 14-1, as shown in FIG. 9F.

As shown in FIG. 9F, the fifth insulation layer 15 may be provided with at least one fourth via K4, and the fourth via K4 penetrates the fifth insulation layer 15 in the thickness direction of the display substrate, and exposes a portion of a surface on a side of the second connection electrode 52 away from the base substrate 10. An orthographic projection of the fourth via K4 on the display substrate may be located within a range of the orthographic projection of the second connection electrode 52 on the display substrate.

(17) Forming a pattern of a fifth conductive layer. Forming the pattern of the fifth conductive layer may include depositing a fifth conductive thin film on a side of the base substrate 10 on which the aforementioned patterns are formed, and patterning the fifth conductive thin film by a patterning process to form the pattern of the fifth conductive layer located on a side of the fifth insulation layer 15, as shown in FIG. 9G.

As shown in FIG. 9G, the fifth conductive layer 15-1 may include at least one drive chip pin 53, and at least a portion of the drive chip pin 53 may be located in the fourth via K4. By way of example, an orthographic projection of the drive chip pin 53 on the display substrate may include the orthographic projection of the fourth via K4 on the display substrate.

As shown in FIG. 9G, the drive chip pin 53 has a groove structure 60, and the groove structure 60 is recessed toward the base substrate 10. The groove structure 60 is configured to accommodate a conductive adhesive or the like to enable an electrical connection between the component to be installed and the data line lead line 50. By way of example, the component to be installed may be a drive chip (Integrated Circuit, IC). The drive chip and the data line lead line 50 are electrically connected via the groove structure 60.

The groove structure 60 has a groove bottom 61, a groove top 62, and a groove wall 63. The groove bottom 61 and the groove top 62 may be provided oppositely to each other in the thickness direction of the display substrate and the groove bottom 61 is closer to the base substrate 10 than the groove top 62. The groove wall 63 may extend in the thickness direction of the display substrate, the groove wall 63 has a first end and a second end provided oppositely to each other, the first end of the groove wall 63 may be connected to the groove bottom 61, and the second end of the groove wall 63 may extend in a direction away from the base substrate 10. The groove top 62 has a first end and a second end provided oppositely to each other, the first end of the groove top 62 may be connected to the second end of the groove wall 63, the second end of the groove top 62 extends in a direction away from the first end, and an orthographic projection of the groove top 62 on the display substrate may be annular. The groove depth H of the groove structure 60 may be between 0.60 micron and 0.65 micron.

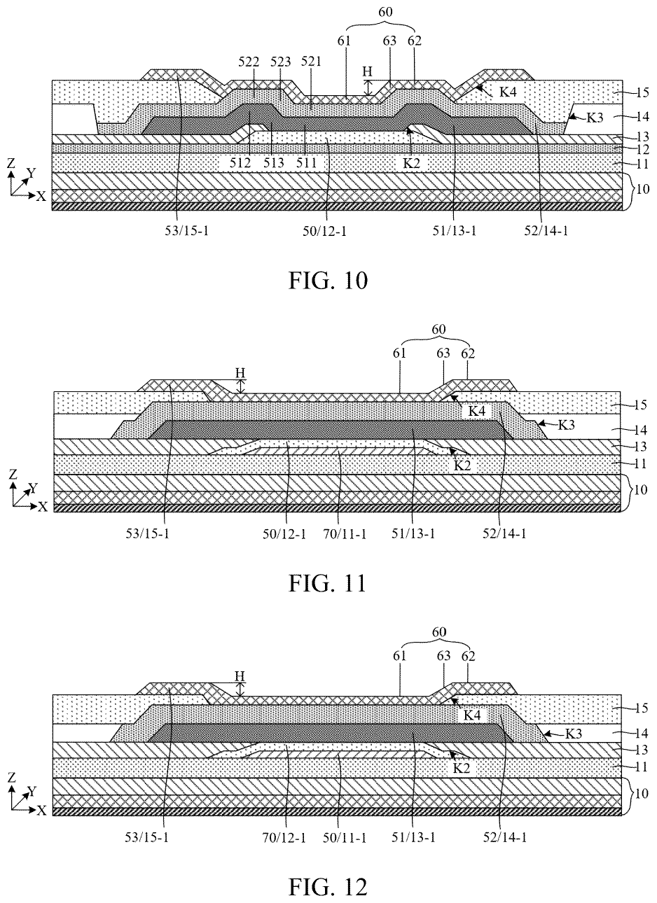

FIG. 10 is a schematic partial sectional view of a drive chip pin of a display substrate according to another embodiment of the present disclosure. As shown in FIG. 10, in a plane perpendicular to the display substrate, the first bezel area of the display substrate may include a base substrate 10, a first insulation layer 11 located on a side of the base substrate 10, a second insulation layer 12 located on a side of the first insulation layer 11 away from the base substrate 10, a second conductive layer 12-1 located on a side of the second insulation layer 12 away from the base substrate 10, a third insulation layer 13 located on a side of the second conductive layer 12-1 away from the base substrate 10, a third conductive layer 13-1 located on a side of the third insulation layer 13 away from the base substrate 10, a fourth conductive layer 14-1 located on a side of the third conductive layer 13-1 away from the base substrate 10, a fourth insulation layer 14 located on a side of the fourth conductive layer 14-1 away from the base substrate 10, a fifth insulation layer 15 located on a side of the fourth conductive layer 14-1 away from the base substrate 10, and a fifth conductive layer 15-1 located on a side of the fifth insulation layer 15 away from the base substrate 10.

As shown in FIG. 10, the second conductive layer 12-1 of the first bezel area of the display substrate may include at least one data line lead line 50. By way of example, multiple data line lead lines 50 may be arranged at intervals in the first direction X and extend in the second direction Y. As shown in FIG. 10, only one data line lead line 50 is illustrated as an example, and the data line lead line 50 extending in the second direction Y is taken as an example. In the first bezel area of the display substrate, the third conductive layer 13-1 may include at least one first connection electrode 51, the fourth conductive layer 14-1 may include at least one second connection electrode 52, and the fifth conductive layer 15-1 may include at least one drive chip pin 53. The drive chip pin 53 is connected to the data line lead line 50 via the second connection electrode 52 and the first connection electrode 51, so that signal transmission may be realized.

In an exemplary embodiment, as shown in FIG. 10, the third conductive layer 13-1 of the first bezel area of the display substrate may include at least one first connection electrode 51. A portion of the first connection electrode 51 is in contact and connected with a portion of the data line lead line 50 through a via located in the third insulation layer 13. As shown in FIG. 10, the third insulation layer 13 may be provided with at least one second via K2, the second via K2 penetrates the third insulation layer 13 in the thickness direction of the display substrate and exposes a portion of a surface on a side of the data line lead line 50 away from the base substrate 10. An orthographic projection of the data line lead line 50 on the display substrate may include an orthographic projection of the second via K2 on the display substrate, the third insulation layer 13 may form a protection for an edge of the data line lead line 50, which may prevent the erosion of the data line lead line by water, oxygen and the like, and may prolong the service life of the display substrate. Other structures of the drive chip pin shown in FIG. 10 may be described with reference to the aforementioned description of the drive chip pin structure shown in FIG. 4, which will not be further described herein.

FIG. 11 is a first schematic partial sectional view of a drive chip pin of a display substrate according to yet another embodiment of the present disclosure. As shown in FIG. 11, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second conductive layer 12-1 located on a side of the first conductive layer 11-1 away from the base substrate 10, a third insulation layer 13 located on a side of the second conductive layer 12-1 away from the base substrate 10, a third conductive layer 13-1 located on a side of the third insulation layer 13 away from the base substrate 10, a fourth conductive layer 14-1 located on a side of the third conductive layer 13-1 away from the base substrate 10, a fourth insulation layer 14 located on a side of the fourth conductive layer 14-1 away from the base substrate 10, a fifth insulation layer 15 located on a side of the fourth conductive layer 14-1 away from the base substrate 10, and a fifth conductive layer 15-1 located on a side of the fifth insulation layer 15 away from the base substrate 10. In this embodiment, the first conductive layer 11-1 located in the first bezel area may also be referred to as a leveling layer.

As shown in FIG. 11, the first conductive layer 11-1 may include at least one leveling block 70, and the leveling block 70 may have a rectangular block shape or the like. In an embodiment of the present disclosure, only one leveling block 70 is illustrated as an example. The second conductive layer 12-1 may include at least one data line lead line 50. By way of example, multiple data line lead lines 50 may be arranged at intervals in the first direction X and extend in the second direction Y. As shown in FIG. 11, only one data line lead line 50 is illustrated as an example, and the data line lead line 50 extending in the second direction Y is taken as an example. In the first bezel area of the display substrate, the third conductive layer 13-1 may include at least one first connection electrode 51, the fourth conductive layer 14-1 may include at least one second connection electrode 52, and the fifth conductive layer 15-1 may include at least one drive chip pin 53, and the drive chip pin 53 is connected to the data line lead line 50 via the second connection electrode 52 and the first connection electrode 51, so that signal transmission may be realized.

As shown in FIG. 11, the orthographic projection of the data line lead line 50 on the display substrate may include an orthographic projection of the leveling block 70 on the display substrate. By way of example, the orthographic projection of the data line lead line 50 on the display substrate may be larger than the orthographic projection of the leveling block 70 on the display substrate. The third insulation layer 13 has at least one second via K2 and an orthographic projection of the second via K2 on the display substrate is located within the orthographic projection of the data line lead line 50 on the display substrate. As shown in FIG. 11, a surface on a side of the data line lead line 50 away from the base substrate 10 is flush with a surface on a side of the third insulation layer 13 away from the base substrate 10, and a drop between the data line lead line 50 and the third insulation layer 13 in the thickness direction of the display substrate may be compensated by providing the leveling block 70. In this way, it is beneficial to flattening the first connection electrode and the second connection electrode to be formed subsequently, a groove depth H of the groove structure to be formed subsequently may be shortened, the dummy connection between the component to be installed (for example, the drive chip) and the display substrate is avoided, and the use reliability of the display substrate may be improved.

In an exemplary embodiment, as shown in FIG. 11, the third conductive layer 13-1 of the first bezel area of the display substrate may include at least one first connection electrode 51. A portion of the first connection electrode 51 is in contact and connected with a portion of the data line lead line 50 through the second via K2 located in the third insulation layer 13. As shown in FIG. 11, the first connection electrode 51 may have a rectangular block shape.

In an exemplary embodiment, as shown in FIG. 11, in the first direction X, the orthographic projection of the first connection electrode 51 on the display substrate may include the orthographic projection of the data line lead line 50 on the display substrate. The first connection electrode 51 may avoid erosion of the data line lead line 50 by water and oxygen and the use reliability of the display substrate may be improved.

In an exemplary embodiment, as shown in FIG. 11, the fourth conductive layer 14-1 of the first bezel area of the display substrate may include at least one second connection electrode 52. A portion of the second connection electrode 52 is in contact and connected with a portion of the first connection electrode 51 through a third via K3 located in the fourth insulation layer 14. As shown in FIG. 11, the second connection electrode 52 may have a rectangular block shape. The orthographic projection of the second connection electrode 52 on the display substrate may include the orthographic projection of the first connection electrode 51 on the display substrate.

In an exemplary embodiment, as shown in FIG. 11, the fifth conductive layer 15-1 of the first bezel area of the display substrate may include at least one drive chip pin 53. A portion of the drive chip pin 53 is in contact and connected with a portion of the second connection electrode 52 through a fourth via K4 located in the fifth insulation layer 15. The orthographic projection of the drive chip pin 53 on the display substrate may be located within a range of the orthographic projection of the second connection electrode 52 on the display substrate.

In an exemplary embodiment, as shown in FIG. 11, the drive chip pin 53 has a groove structure 60, and the groove structure 60 is recessed toward the base substrate 10. The groove structure 60 is configured to accommodate a conductive adhesive to enable an electrical connection between the component to be installed (for example, the drive chip) and the data line lead line 50. The groove structure 60 may play a limiting role for the conductive particles in the conductive adhesive. After the component to be installed is assembled in place on the display substrate, the conductive particles are compressed by the component to be installed and may be stably maintained within the groove structure 60, so that a good connectivity between the component to be installed and the display substrate may be ensured, and the reliability of the display substrate may be improved.

In an exemplary embodiment, as shown in FIG. 11, the groove structure 60 has a groove bottom 61, a groove top 62, and a groove wall 63. The groove bottom 61 and the groove top 62 may be provided oppositely to each other in the thickness direction of the display substrate and the groove bottom 61 is closer to the base substrate 10 than the groove top 62. The groove wall 63 may extend in the thickness direction of the display substrate, the groove wall 63 has a first end and a second end provided oppositely to each other, the first end of the groove wall 63 may be connected to the groove bottom 61, and the second end of the groove wall 63 may extend in a direction away from the base substrate 10. The groove top 62 has a first end and a second end provided oppositely to each other, the first end of the groove top 62 may be connected to the second end of the groove wall 63, the second end of the groove top 62 extends in a direction away from the first end, and an orthographic projection of the groove top 62 on the display substrate may be annular. By way of example, the orthographic projection of the groove top 62 on the display substrate may be circular annular, rectangular annular, or the like.

In an exemplary embodiment, as shown in FIG. 11, there is a distance H (that is the groove depth of the groove structure 60) between the groove bottom 61 and the groove top 62 in the thickness direction of the display substrate, and the distance H may range from 0.40 micron to 0.55 micron. For example, the distance H may be 0.50 micron. Alternatively, the distance H may be 0.45 micron.

FIG. 12 is a second schematic partial sectional view of a drive chip pin of a display substrate according to yet another embodiment of the present disclosure. As shown in FIG. 12, in a plane perpendicular to the display substrate, the first bezel area of the display substrate may include a base substrate 10, a first insulation layer 11 located on a side of the base substrate 10, a first conductive layer 11-1 located on a side of the first insulation layer 11 away from the base substrate 10, a second conductive layer 12-1 located on a side of the first conductive layer 11-1 away from the base substrate 10, a third insulation layer 13 located on a side of the second conductive layer 12-1 away from the base substrate 10, a third conductive layer 13-1 located on a side of the third insulation layer 13 away from the base substrate 10, a fourth conductive layer 14-1 located on a side of the third conductive layer 13-1 away from the base substrate 10, a fourth insulation layer 14 located on a side of the fourth conductive layer 14-1 away from the base substrate 10, a fifth insulation layer 15 located on a side of the fourth conductive layer 14-1 away from the base substrate 10, and a fifth conductive layer 15-1 located on a side of the fifth insulation layer 15 away from the base substrate 10. As shown in FIG. 12, the first conductive layer 11-1 may include at least one data line lead line 50. The second conductive layer 12-1 may include at least one leveling block 70, and in this embodiment, the second conductive layer 12-1 located in the first bezel area may also be referred to as a leveling layer. Other structures of the drive chip pin may be described with reference to the aforementioned description of the structure of the drive chip pin shown in FIG. 11, which will not be further described herein.

Taking a structure of the drive chip pin of the display substrate shown in FIG. 12 as an example, the manufacturing process of the drive chip pin of the display substrate may include the following steps (21) to (28).

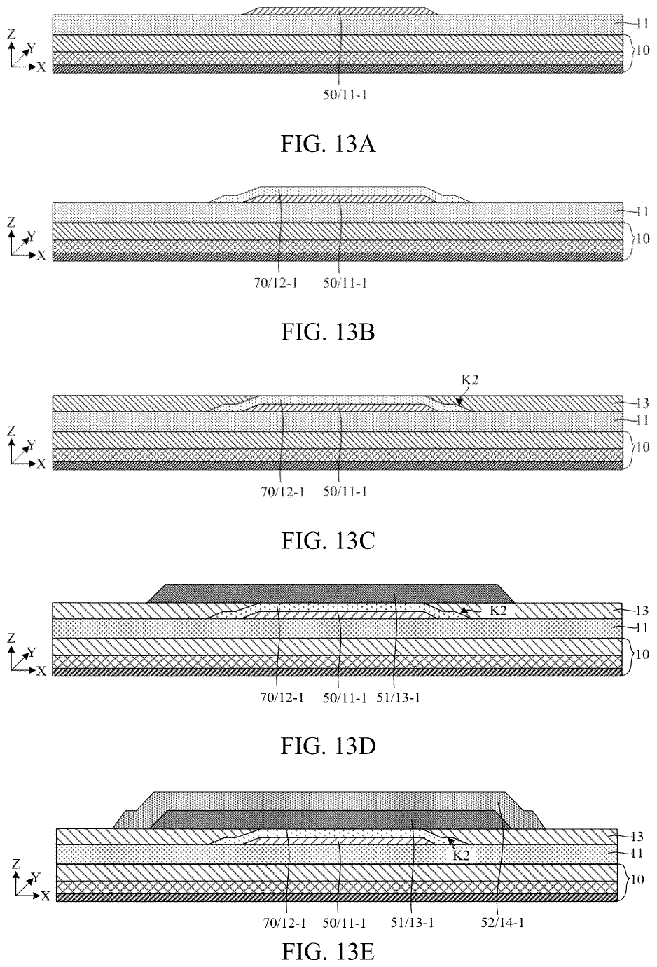

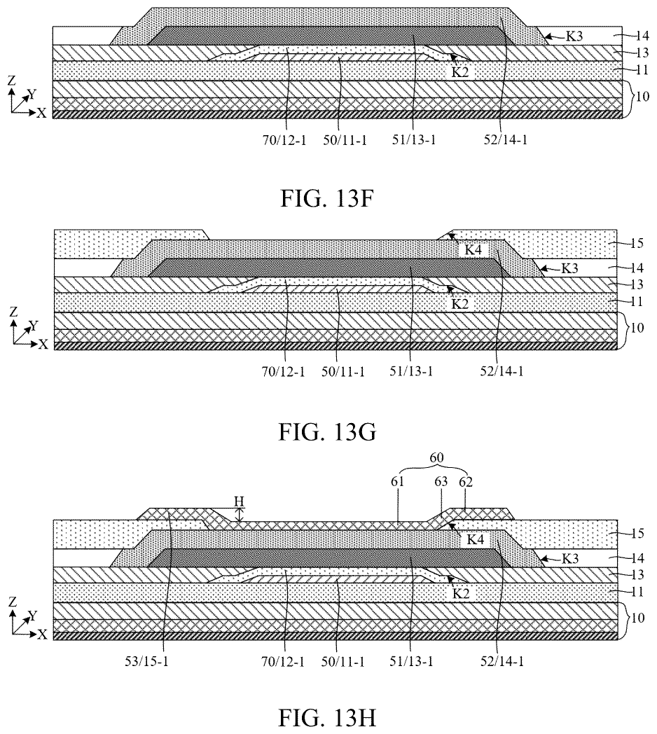

(21) Forming a pattern of a first conductive layer. Forming the pattern of the first conductive layer may include sequentially depositing a first insulation thin film and a first conductive thin film on a side of a base substrate 10, and patterning the first conductive thin film by a patterning process to form a first insulation layer 11 and the pattern of the first conductive layer located on a side of the first insulation layer 11 on a side of the base substrate 10. As shown in FIG. 13A, the first conductive layer 11-1 may at least include one data line lead line 50.

(22) Forming a pattern of a second conductive layer. Forming the pattern of the second conductive layer may include depositing a second conductive thin film on a side of the base substrate 10 on which the aforementioned pattern is formed, and patterning the second conductive thin film by a patterning process to form the pattern of the second conductive layer on a side of the first conductive layer 11-1, as shown in FIG. 13B.

As shown in FIG. 13B, the second conductive layer 12-1 may include at least one leveling block 70. In the first direction X, an orthographic projection of the leveling block 70 on the display substrate may include an orthographic projection of the data line lead line 50 on the display substrate.

(23) Forming a pattern of a third insulation layer. Forming the pattern of the third insulation layer may include depositing a third insulation thin film on a side of the base substrate 10 on which the aforementioned patterns are formed, and patterning the third insulation thin film by a patterning process to form the pattern of the third insulation layer on a side of the second conductive layer 12-1, as shown in FIG. 13C.

As shown in FIG. 13C, the third insulation layer 13 may at least include one second via K2, the second via K2 penetrates a thickness of the third insulation layer 13 and exposes at least a portion of a surface on a side of the leveling block 70 away from the base substrate 10. A surface on a side of the leveling block 70 away from the base substrate 10 may be flush with a surface on a side of the third insulation layer 13 away from the base substrate 10.

(24) Forming a pattern of a third conductive layer. Forming the pattern of the third conductive layer may include depositing a third conductive thin film on a side of the base substrate 10 on which the aforementioned patterns are formed, and patterning the third conductive thin film by a patterning process to form the pattern of the third conductive layer on a side of the third insulation layer 13, as shown in FIG. 13D.

As shown in FIG. 13D, the third conductive layer 13-1 may include at least one first connection electrode 51, and a portion of the first connection electrode 51 may be in contact and connected with a portion of the leveling block 70 through a second via K2 located in the third insulation layer 13. The first connection electrode 51 may have a rectangular block shape. In the first direction X, an orthographic projection of the first connection electrode 51 on the display substrate may include an orthographic projection of the leveling block 70 on the display substrate.

(25) Forming a pattern of a fourth conductive layer. Forming the pattern of the fourth conductive layer may include depositing a fourth conductive thin film on a side of the base substrate 10 on which the aforementioned patterns are formed, and patterning the fourth conductive thin film by a patterning process to form the pattern of the fourth conductive layer on a side of the third conductive layer 13-1, as shown in FIG. 13E.

As shown in FIG. 13E, the fourth conductive layer 14-1 may at least include one second connection electrode 52, and the second connection electrode 52 is in contact with a surface on a side of the first connection electrode 51 away from the base substrate 10. An orthographic projection of the second connection electrode 52 on the display substrate may include the orthographic projection of the first connection electrode 51 on the display substrate.

(26) Forming a pattern of a fourth insulation layer. Forming the pattern of the fourth insulation layer may include depositing a fourth insulation thin film on a side of the base substrate 10 on which the aforementioned patterns are formed, and patterning the fourth insulation thin film by a patterning process to form the pattern of the fourth insulation layer on a side of the fourth conductive layer 14-1, as shown in FIG. 13F.

As shown in FIG. 13F, the fourth insulation layer 14 may at least include one third via K3, the third via K3 exposes at least a portion of a surface on a side of the second connection electrode 52 away from the base substrate 10.

(27) Forming a pattern of a fifth insulation layer. Forming the pattern of the fifth insulation layer may include depositing a fifth insulation thin film on a side of the base substrate 10 on which the aforementioned patterns are formed, and patterning the fifth insulation thin film by a patterning process to form the pattern of the fifth insulation layer on a side of the fourth conductive layer 14-1, as shown in FIG. 13G.

As shown in FIG. 13G, the fifth insulation layer 15 may include at least one fourth via K4 and the fourth via K4 penetrates the fifth insulation layer 15 in the thickness direction of the display substrate, and exposes a portion of a surface on a side of the second connection electrode 52 away from the base substrate 10. The fourth via K4 connects the drive chip pin to be formed subsequently to the second connection electrode 52 through the fourth via K4.

(28) Forming a pattern of a fifth conductive layer. Forming the pattern of the fifth conductive layer may include depositing a fifth conductive thin film on a side of the base substrate 10 on which the aforementioned patterns are formed, and patterning the fifth conductive thin film by a patterning process to form the pattern of the fifth conductive layer on a side of the fifth insulation layer 15, as shown in FIG. 13H.

As shown in FIG. 13H, the fifth conductive layer 15-1 may at least include one drive chip pin 53, a portion of the drive chip pin 53 may be located within the fourth via K4, and the drive chip pin 53 and the second connection electrode 52 are connected through the fourth via K4.

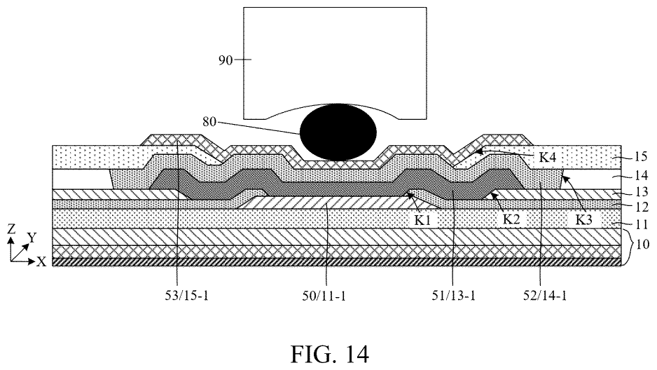

FIG. 14 is a schematic partial sectional view of a display device according to an embodiment of the present disclosure. As shown in FIG. 14, the display device includes a display substrate, a conductive adhesive 80, and a component to be installed. By way of example, the component to be installed may be an electrical element conventional in the display field. In an embodiment of the present disclosure, the component to be installed being a drive chip 90 (Integrated Circuit, IC) is taken as an example. The drive chip pin 90 may be connected to the drive chip pin 53 of the first bezel area of the display substrate through the conductive adhesive 80 and FIG. 14 is a schematic partial sectional view of the drive chip pin of the first bezel area of the display device.

As shown in FIG. 14, the conductive adhesive 80 may include multiple conductive particles, and a portion of the conductive particles may be located in the groove structure 60 in the first bezel area. After the drive chip 90 is assembled in place, the conductive particles may be compressed between the drive chip 90 and the groove structure 60, so that the drive chip 90 and the display substrate have a good electrical connectivity, and defects such as dark lines in the first bezel area may be avoided, and reliability of the display device may be improved.

Another embodiment of the present disclosure provides a display device and the display device includes the display substrate illustrated in any one of the above embodiments. The display device may be any product or component with a display function, such as a mobile phone, a tablet computer, a television, a display, a laptop computer, a digital photo frame, and a navigator, and an embodiment of the present disclosure is not limited thereto.

Although the embodiments disclosed in the present disclosure are described as above, the described contents are only embodiments which are adopted in order to facilitate understanding of the present disclosure, and are not intended to limit the present disclosure. It should be noted that the above examples or embodiments are exemplary only but not restrictive. Therefore, the present disclosure is not limited to what is specifically shown and described herein. Various modifications, substitutions or omissions may be made in forms and details of implementation modes without departing from the scope of the present disclosure.

1. A display substrate, comprising:
a base substrate, comprising a display area and a first bezel area located on a side of the display area;
a plurality of sub-pixels, located in the display area;
a plurality of data lines, located in the display area, the plurality of data lines being electrically connected to the plurality of sub-pixels;
a plurality of data line lead lines, located in the first bezel area, the plurality of data line lead lines being electrically connected to the plurality of data lines; and
a plurality of drive chip pins, located in the first bezel area, a drive chip pin being electrically connected to a data line lead line, and the plurality of drive chip pins being located on a side of the plurality of data line lead lines away from the base substrate;
wherein at least one groove structure is provided on a surface on a side of the drive chip pin away from the base substrate, the at least one groove structure comprises a groove bottom and a groove wall connecting the groove bottom, the at least one groove structure has a groove depth in a thickness direction of the display substrate, and the groove depth ranges from 0.40 micron to 0.65 micron.

2. The display substrate according to claim 1, wherein in a plane perpendicular to the display substrate, the first bezel area comprises a first metal layer, a second metal layer, a third metal layer, and a fourth metal layer that are provided on a side of the base substrate and are stacked sequentially; the first metal layer comprises the plurality of data line lead lines and the fourth metal layer comprises the plurality of drive chip pins.

3. The display substrate according to claim 2, wherein in the plane perpendicular to the display substrate, the first bezel area further comprises at least one insulation layer, and the at least one insulation layer is located between the first metal layer and the second metal layer; the second metal layer comprises at least one connection electrode, and a portion of the connection electrode is located in a via of the at least one insulation layer, and is in contact and connected with a surface on a side of the data line lead line away from the base substrate.

4. The display substrate according to claim 3, wherein the at least one insulation layer comprises a first inorganic layer and a second inorganic layer, and the second inorganic layer is farther away from the base substrate than the first inorganic layer; in a line width direction of the data line lead line, an orthographic projection of a via provided in the first inorganic layer on the display substrate is located within an orthographic projection of the data line lead line on the display substrate, an orthographic projection of a via provided in the second inorganic layer on the display substrate comprises the orthographic projection of the data line lead line on the display substrate, and the orthographic projection of the via provided in the second inorganic layer on the display substrate is larger than the orthographic projection of the data line lead line on the display substrate.

5. The display substrate according to claim 3, wherein one insulation layer is provided between the first metal layer and the second metal layer, and in a line width direction of the data line lead line, an orthographic projection of the via provided in the insulation layer on the display substrate is located within an orthographic projection of the data line lead line on the display substrate.

6. The display substrate according to claim 2, wherein in the plane perpendicular to the display substrate, the display area comprises a first gate metal layer, a second gate metal layer, a first source-drain metal layer, and a second source-drain metal layer that are provided on a side of the base substrate and stacked sequentially; the first metal layer and the first gate metal layer are structures provided in a same layer, the second metal layer and the first source-drain metal layer are structures provided in a same layer, and the third metal layer and the second source-drain metal layer are structures provided in a same layer.

7. The display substrate according to claim 2, wherein in the plane perpendicular to the display substrate, the display area comprises a first gate metal layer, a second gate metal layer, a first source-drain metal layer, and a second source-drain metal layer that are provided on a side of the base substrate and stacked sequentially; the first metal layer and the second gate metal layer are structures provided in a same layer, the second metal layer and the first source-drain metal layer are structures provided in a same layer, and the third metal layer and the second source-drain metal layer are structures provided in a same layer.

8. The display substrate according to claim 2, wherein the second metal layer comprises at least one first connection electrode and the third metal layer comprises at least one second connection electrode; at least a portion of a surface on a side of the second connection electrode away from the base substrate is in contact and connected with the groove structure of the drive chip pin, and a portion of a surface on a side of the first connection electrode close to the base substrate is in contact and connected with the data line lead line.

9. The display substrate according to claim 8, wherein the first connection electrode has a first sub-groove, the second connection electrode has a second sub-groove, an orthographic projection of the groove structure of the drive chip pin on the display substrate is located within an orthographic projection of the second sub-groove on the display substrate, and the orthographic projection of the second sub-groove on the display substrate is located within an orthographic projection of the first sub-groove on the display substrate.

10. The display substrate according to claim 2, wherein in the plane perpendicular to the display substrate, the first bezel area further comprises a leveling layer and the leveling layer is located between the base substrate and the first metal layer; the leveling layer comprises at least one leveling block; in a line width direction of the data line lead line, an orthographic projection of the data line lead line on the display substrate comprises an orthographic projection of the leveling block on the display substrate.

11. The display substrate according to claim 2, wherein in the plane perpendicular to the display substrate, the first bezel area further comprises a leveling layer, the leveling layer is located between the first metal layer and the second metal layer, and the leveling layer comprises at least one leveling block; in a line width direction of the data line lead line, an orthographic projection of the leveling block on the display substrate comprises an orthographic projection of the data line lead line on the display substrate, and the data line lead line is electrically connected to the groove structure of the drive chip pin via the leveling block.

12. The display substrate according to claim 10, wherein in the plane perpendicular to the display substrate, the first bezel area further comprises at least one insulation layer, the at least one insulation layer is located between the first metal layer and the second metal layer, and a surface on a side of the at least one insulation layer away from the base substrate is flush with a surface on a side of the data line lead line and the leveling block away from the base substrate.

13. The display substrate according to claim 12, wherein the second metal layer comprises at least one first connection electrode and the third metal layer comprises at least one second connection electrode; the data line lead line is connected to the groove structure of the drive chip pin via the first connection electrode and the second connection electrode; and
wherein a surface on a side of the first connection electrode away from the base substrate is planar.

14. The display substrate according to claim 13, wherein a surface on a side of the second connection electrode away from the base substrate is planar.

15. The display substrate according to claim 10, wherein in the plane perpendicular to the display substrate, the display area comprises a first gate metal layer, a second gate metal layer, a first source-drain metal layer, and a second source-drain metal layer that are provided on a side of the base substrate and stacked sequentially; the second metal layer and the first source-drain metal layer are structures provided in a same layer, and the third metal layer and the second source-drain metal layer are structures provided in a same layer; and
the leveling layer and one of the first gate metal layer and the second gate metal layer are structures provided in a same layer, and the first metal layer and the other of the first gate metal layer and the second gate metal layer are structures provided in a same layer.

16. A display device, comprising the display substrate according to claim 1.

17. The display substrate according to claim 3, wherein in the plane perpendicular to the display substrate, the display area comprises a first gate metal layer, a second gate metal layer, a first source-drain metal layer, and a second source-drain metal layer that are provided on a side of the base substrate and stacked sequentially; the first metal layer and the first gate metal layer are structures provided in a same layer, the second metal layer and the first source-drain metal layer are structures provided in a same layer, and the third metal layer and the second source-drain metal layer are structures provided in a same layer.

18. The display substrate according to claim 3, wherein in the plane perpendicular to the display substrate, the display area comprises a first gate metal layer, a second gate metal layer, a first source-drain metal layer, and a second source-drain metal layer that are provided on a side of the base substrate and stacked sequentially; the first metal layer and the second gate metal layer are structures provided in a same layer, the second metal layer and the first source-drain metal layer are structures provided in a same layer, and the third metal layer and the second source-drain metal layer are structures provided in a same layer.

19. The display substrate according to claim 3, wherein the second metal layer comprises at least one first connection electrode and the third metal layer comprises at least one second connection electrode; at least a portion of a surface on a side of the second connection electrode away from the base substrate is in contact and connected with the groove structure of the drive chip pin, and a portion of a surface on a side of the first connection electrode close to the base substrate is in contact and connected with the data line lead line.

20. The display substrate according to claim 11, wherein in the plane perpendicular to the display substrate, the first bezel area further comprises at least one insulation layer, the at least one insulation layer is located between the first metal layer and the second metal layer, and a surface on a side of the at least one insulation layer away from the base substrate is flush with a surface on a side of the data line lead line and the leveling block away from the base substrate.
